(19) United States
(12) Patent Application Publication
(10) Pub. No.: US 2006/0024941 A1
(43) Pub. Date: Feb. 2, 2006

(54) Method of forming metal interconnect of semiconductor device

(75) Inventors: Jeong-hoon Son, Yongin-si (KR); Hyeok-sang Oh, Suwon-si (KR); Seong-il Kim, Yongin-si (KR); Ju-hyuck Chung, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/191,518

(22) Filed: Jul. 28, 2005

(30) Foreign Application Priority Data
Jul. 30, 2004 (KR) 10-2004-0060277

(51) Int. Cl. H01L 21/44

(52) U.S. Cl. 438/597

(57) ABSTRACT

In a method of forming a metal interconnect of a semiconductor device using a damascene process, an etch stop layer and an insulating layer are successively formed on a semiconductor substrate, into which a conductive pattern is filled. Next, the etch stop layer and the insulating layer are patterned so that an opening for exposing the etch stop layer is formed. Subsequently, a first diffusion barrier layer is formed along inner surfaces of the opening. The first diffusion barrier layer on a bottom surface of the opening and the etch stop layer are removed through an etch process using a sputtering method. Finally, a conductive material which is electrically connected to the conductive pattern is filled into the opening.

### RELATED APPLICATIONS

This application claims priority from Korean Patent Application No. 10-2004-0060277 filed on Jul. 30, 2004 in the Korean Intellectual Property Office, the disclosure of which is incorporated herein by reference in its entirety.

### BACKGROUND OF THE INVENTION

1. Field of the Invention

The present invention relates to a method of forming a metal interconnect of a semiconductor device, and more particularly, to a method of forming a metal interconnect of a semiconductor device using a damascene process.

2. Description of the Related Art

As transistors are generated with ever-smaller geometries, logic devices having higher operation speeds and higher integration are produced. With further integration, the size of interconnects continued to decrease. However, as interconnects have become smaller, a delay problem caused by the interconnects has become more acute, and thus, the delay caused by the interconnects is an important consideration in high-speed logic devices.

In view of the above, interconnects using copper, which has lower resistance and higher electromigration (EM) tolerance than an aluminum alloy, which was conventionally and generally used as a material of interconnects of large scale integrated (LSI) semiconductor devices, have been actively developed. However, there are problems associated with the use of copper: it is difficult to etch and is rapidly oxidized during a process for forming the interconnects. Accordingly, a damascene process is used to form a copper interconnect. The damascene process is used to form trenches, which are formed between upper layer interconnects for respectively isolating the upper layer interconnects formed on insulating layers, and vias for connecting the upper layer interconnects to lower layer interconnects or a substrate, to fill the trenches and the vias with copper, and to planarize the trenches and the vias by a chemical mechanical polishing (CMP) process.

The damascene process can generally be categorized as a dual damascene process and a single damascene process. In the dual damascene process, after successively forming the trenches and the vias, the trenches and the vias are simultaneously filled with copper. On the other hand, in the single damascene process, after forming only one of the trenches and the vias, the trenches or the vias are filled with copper.

Hereinafter, regions between the trenches, which are referred to as interconnect regions, are connected to the lower layer interconnects through the vias and filled into the upper layer interconnects, will be explained.

FIGS. 1 to 5 are cross-sectional views showing a method of forming a metal interconnect of a semiconductor device in accordance with a conventional process used to form a metal interconnect.

As shown in FIG. 1, first, a first etch stop layer 21 and a first insulating layer 31 are successively formed on a semiconductor substrate 10 into which a conductive pattern 11 is filled, and then a second etch stop layer 22 and a second insulating layer 32 are successively formed on the first insulating layer 31.

Referring to FIG. 2, photoresist is coated on top of the second insulating layer 32 and patterned so that a first photoresist pattern PR1, in which an area having a first width W1 on the upper surface of the second insulating layer 32 is partly exposed, is formed. The first and second insulating layers 31 and 32 and the second etch stop layer 22 are etched using the first photoresist pattern PR1 as an etch mask. Here, the etch process of the first and second insulating layers 31 and 32 and the second etch stop layer 22 is performed until the first etch stop layer 21 is exposed. Thus, a via 40 having the first width W1 is formed. Subsequently, the first photoresist pattern PR1 is removed.

Referring to FIG. 3, a second photoresist pattern PR2 having an opening with a second width W2 wider than the first width W1 is formed on the second insulating layer 32 in which the via 40 is formed. Subsequently, the second insulating layer 32 is etched using the second photoresist pattern PR2 as an etch mask. Here, the etch process of the second insulating layer 32 is performed until the second etch stop layer 22 is exposed. Thus, an interconnect area 50 having the second width W2 is formed within the second insulating layer 32. Subsequently, the second photoresist pattern PR2 is removed.

Referring to FIG. 4, the first etch stop layer 21 exposed through the via 40 and the second etch stop layer 22 exposed through the interconnect area 50 are etched by a dry etch process. Thus, the conductive pattern 11 is exposed at a lower portion of the via 40. Meanwhile, after the dry etch process, a strip process for removing remaining etch gases and an oxide layer, or the like, formed on the conductive pattern 11 is performed. Here, areas exposed in the atmosphere of the first and second etch stop layers 21 and 22 consisting of SiN, or the like, are easily oxidized so that the exposed areas together with the remaining etch gases and the oxide layer are removed during the strip process. In this way, undercuts having negatively pitched slopes are generated.

In the event that such undercuts are generated, there is a problem in that a diffusion barrier layer and a seed layer are discontinuously deposited in a process for forming the diffusion barrier layer and a process for forming the seed layer subsequent to the strip process.

That is, as shown in FIG. 5, a diffusion barrier layer 60 which must be evenly deposited along steps on the semiconductor substrate 10 is deposited discontinuously. As a result, there is a problem that an upper conductive material which must be electrically connected to the conductive pattern 11 can become delaminated from the conductive pattern 11 in an electrochemical plating (ECP) process and an anneal process subsequent to the deposition process of the diffusion barrier layer 60.

### SUMMARY OF THE INVENTION

To address the above-described limitations, the present invention provides a method of forming a metal interconnect of a semiconductor device, in which a profile failure such as an undercut of an etch stop layer is prevented so that a conductive material can be conformally formed in a via or an interconnect region.

The present invention also provides a method of forming a metal interconnect of a semiconductor device, in which after a conductive pattern on a semiconductor substrate is exposed, a next process subsequent to the exposure of the conductive pattern is successively performed without a stationary period in an exposed state of the conductive pattern so that pollution and oxidation of the conductive pattern can be prevented.

The present invention further provides a simplified method of forming a metal interconnect of a semiconductor device.

In one aspect, the present invention is directed to a method of forming a metal interconnect of a semiconductor device comprising: successively forming an etch stop layer and an insulating layer on a semiconductor substrate into which a conductive pattern is filled; patterning the insulating layer and forming an opening to expose the etch stop layer; forming a first diffusion barrier layer along inner surfaces of the opening; removing the first diffusion barrier layer and the etch stop layer on a bottom surface of the opening through an etch process using a sputtering method; and filling the opening with a conductive material which is electrically connected to the conductive pattern.

In one embodiment, the opening is a via or an interconnect region.

In another embodiment, the method further comprises, after the removing of the first diffusion barrier layer and the etch stop layer on the bottom surface of the opening, forming a second diffusion barrier layer on the inner surfaces of the opening.

In another embodiment, the first and second diffusion barrier layers are formed of a Ta layer, a TaN layer, a Ti layer, a TiN layer, a WN layer, or combinations thereof.

In another embodiment, the first diffusion barrier layer is formed of a TaN layer and the second diffusion barrier layer is formed of a Ta layer.

In another embodiment, the first and second diffusion barrier layers are formed by a sputtering method or a chemical vapor deposition (CVD) method.

In another embodiment, the etch process using the sputtering method in the removing of the first diffusion barrier layer and the etch stop layer is used to accelerate an argon particle in a plasma state toward the first diffusion barrier layer and the etch stop layer on the bottom surface of the opening and to push atoms forming the first diffusion barrier layer and the etch stop layer at the bottom surface of the opening into other positions, thereby removing the first diffusion barrier layer and the etch stop layer.

In another aspect, the present invention is directed to a method of forming a metal interconnect of a semiconductor device comprising: successively forming a first etch stop layer and a first insulating layer on a semiconductor substrate into which a conductive pattern is filled; successively forming a second etch stop layer and a second insulating layer on the first insulating layer; patterning the second insulating layer, the second etch stop layer and the first insulating layer to forming a via to expose the first etch stop layer; patterning the second insulating layer to form an interconnect area at a top region of the via having a width equal to or greater than the via; forming a first diffusion barrier layer along inner surfaces of the via; removing the first diffusion barrier layer and the first etch stop layer on a bottom surface of the via through an etch process using a sputtering method; and filling the via and the interconnect area with a conductive material which is electrically connected to the conductive pattern.

In one embodiment, the method further comprises after the removing of the first diffusion barrier layer and the first etch stop layer on the bottom surface of the via, forming a second diffusion barrier layer on the inner surfaces of the via.

In another embodiment, the first and second diffusion barrier layers are formed of a Ta layer, a TaN layer, a Ti layer, a TiN layer, a WN layer, or combinations thereof.

In another embodiment, the first diffusion barrier layer is formed of a TaN layer and the second diffusion barrier layer is formed of a Ta layer.

In another embodiment, the first and second diffusion barrier layers are formed by a sputtering method or a chemical vapor deposition (CVD) method.

In another embodiment, the etch process using the sputtering method in the removing of the first diffusion barrier layer and the first etch stop layer is used to accelerate an argon particle in a plasma state toward the first diffusion barrier layer and the etch stop layer on the bottom surface of the via and to push atoms forming the first diffusion barrier layer and the etch stop layer at the bottom surface of the via into other positions, thereby removing the first diffusion barrier layer and the etch stop layer.

In another aspect, the present invention is directed to a method of forming a metal interconnect of a semiconductor device comprising: successively forming an etch stop layer and an insulating layer on a semiconductor substrate into which a conductive pattern is filled; patterning the insulating layer and forming a via to expose the etch stop layer; patterning the insulating layer to etch the insulating layer, on which the via is formed, to a predetermined depth from an upper part of the insulating layer and adjusting the predetermined depth by adjusting the etching time of the insulating layer to form an interconnect area at a top region of the via having a width equal to or greater than the via; forming a first diffusion barrier layer along steps on inner surfaces of the via; removing the first diffusion barrier layer and the etch stop layer on a bottom surface of the via through an etch process using a sputtering method; and filling the via and the interconnect area with a conductive material which is electrically connected to the conductive pattern.

In one embodiment, the method further comprises, after the removing of the first diffusion barrier layer and the etch stop layer on the bottom surface of the via, forming a second diffusion barrier layer along the inner surfaces of the via.

In another embodiment, the first and second diffusion barrier layers are formed of a Ta layer, a TaN layer, a Ti layer, a TiN layer, a WN layer, or combinations thereof.

In another embodiment, the first diffusion barrier layer is formed of a TaN layer and the second diffusion barrier layer is formed of a Ta layer.

In another embodiment, the first and second diffusion barrier layers are formed by a sputtering method or a chemical vapor deposition (CVD) method.

In another embodiment, the etch process using the sputtering method in the removing of the first diffusion barrier layer and the etch stop layer is used to accelerate an argon particle in a plasma state toward the first diffusion barrier layer and the etch stop layer on the bottom surface of the via and to push atoms forming the first diffusion barrier layer and the etch stop layer at the bottom surface of the via into other positions, thereby removing the first diffusion barrier layer and the etch stop layer.

### BRIEF DESCRIPTION OF THE DRAWINGS

The foregoing and other objects, features and advantages of the invention will be apparent from the more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIGS. 1 to 5 are cross-sectional views showing a conventional method of forming a metal interconnect of a semiconductor device.

FIGS. 6 to 13 are cross-sectional views showing a method of forming a metal interconnect of a semiconductor device in the order of a process according to a first embodiment of the present invention.

FIGS. 14 and 15 are cross-sectional views explaining a method of forming a metal interconnect of a semiconductor device, according to a second embodiment of the present invention.

FIGS. 16 to 23 are cross-sectional views showing a method of forming a metal interconnect of a semiconductor device in the order of a process according to a third embodiment of the present invention.

FIGS. 24 to 30 are cross-sectional views showing a method of forming a metal interconnect of a semiconductor device in the order of a process according to a fourth embodiment of the present invention.

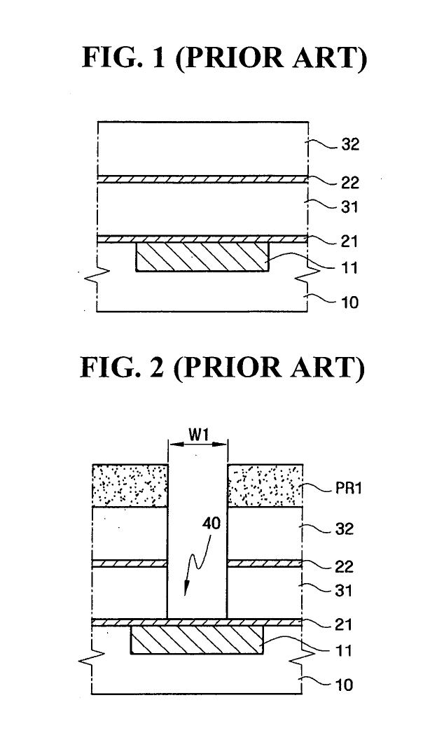

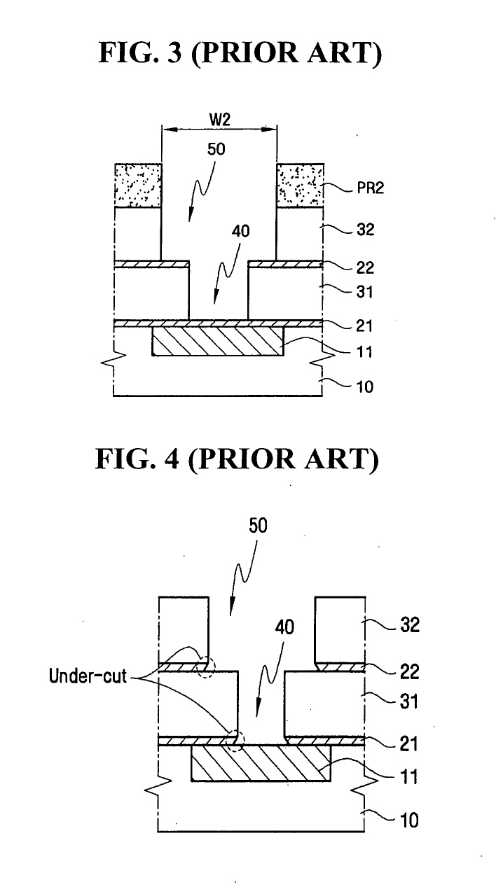

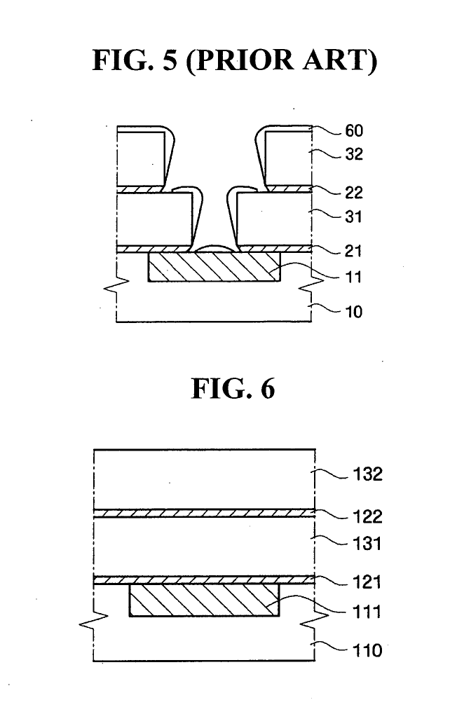

### DETAILED DESCRIPTION OF THE INVENTION

The present invention will now be described more fully hereinafter with reference to the accompanying drawings, in which preferred embodiments of the invention are shown. This invention may, however, be embodied in different forms and should not be construed as limited to the embodiments set forth herein. Like numbers refer to like elements throughout the specification.

First, a method of forming a metal interconnect of a semiconductor device according to a first embodiment of the present invention will now be described with reference to FIGS. 6 to 13.

FIGS. 6 to 13 are cross-sectional views showing a method of forming a metal interconnect of a semiconductor device in the order of a process according to a first embodiment of the present invention.

As shown in FIG. 6, a semiconductor substrate 110 is prepared into which a conductive pattern 111, which will be a lower interconnect, is filled. A first etch stop layer 121 and a first insulating layer 131 are formed on the semiconductor substrate 110. Subsequently, a second etch stop layer 122 and a second insulating layer 132 are successively formed on the first insulating layer 131.

Examples of the semiconductor substrate 110 include a silicon substrate, a silicon on insulator (SOI) substrate, a gallium arsenide substrate, a silicon germanium substrate, a ceramic substrate, a quartz substrate, or a glass substrate for display. Various kinds of active elements and passive elements can be formed on the semiconductor substrate 110. The conductive pattern 111 can be consisted of various kinds of interconnect materials, for example, copper, a copper alloy, aluminum, an aluminum alloy, or the like. It is preferable that the conductive pattern 111 is formed of copper in order to minimize resistance.

The first etch stop layer 121 is formed to prevent an electrical characteristic of the conductive pattern 111, which is a lower interconnect, from being damaged by exposure of the conductive pattern 111 in an etch process for forming a via, which will be described later. Thus, the first etch stop layer 121 is formed of a material having a large etch selectivity with respect to the first insulating layer 131 formed thereon. Further, the second etch stop layer 122 is formed to prevent the first insulating layer 131 formed under the second etch stop layer 122 from being exposed in an etch process for forming an upper interconnect area which will be described later. Thus, the second etch stop layer 122 is formed of a material having a large etch selectivity with respect to the second insulating layer 132 formed thereon. Preferably, the first and second etch stop layers 121 and 122 are formed of SiC, SiN, SiCN, or the like, whose dielectric constants are in the range of 4-5. The first and second etch stop layers 121 and 122 have as thin a thickness as possible considering that the thicknesses of the first and second etch stop layers 121 and 122 have an effect on the dielectric constants of all of insulating layers. However, the first etch stop layers 121 and 122 have sufficient thickness to perform the function of an etch stop layer.

The first and second insulating layers 131 and 132 can comprise a low dielectric constant (low-k) material characteristic of organic compound and the existing equipments and processes. Further, the first and second insulating layers 131 and 132 are formed of hybrid low-k material having all of characteristics of inorganic substances whose thermal stability is excellent. To prevent RC signal delay between the conductive pattern 111, which is the lower interconnect, and the via to be formed and the upper interconnect and suppress mutual interference and increase of power consumption, the first and second insulating layers 131 and 132 are formed of hybrid material, the dielectric constant of which is 3 or less. Most preferably, low −k OrganoSilicateGlass (OSG) is used to form the first and second insulating layers 131 and 132. The first and second insulating layers 131 and 132 can be formed using plasma enhanced chemical vapor deposition (PECVD), high-density plasma-CVD (HDP-CVD), atmospheric pressure CVD (APCVD), spin coating, or the like.

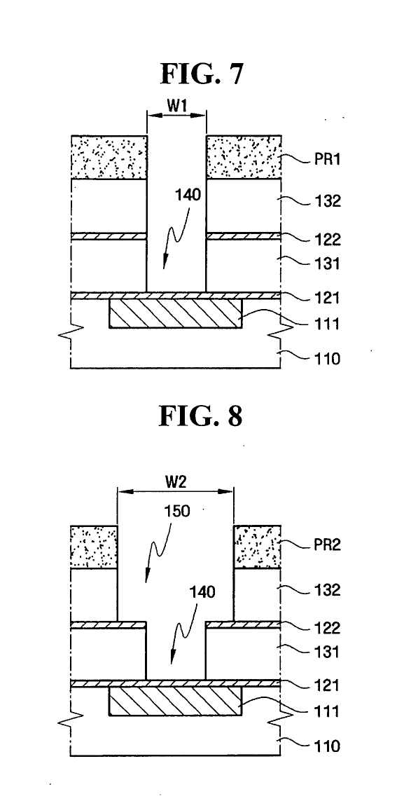

Referring to FIG. 7, photoresist is coated on top of the second insulating layer 132 and patterned so that a first photoresist pattern PR1, in which an upper surface of the second insulating layer 132 is partly exposed as wide as a first width W1, is formed. Here, it is preferable that when an opening of the first photoresist pattern PR1 is projected on the conductive pattern 111, the opening of the first photoresist pattern PR1 is positioned within the width of the conductive pattern 111.

Subsequently, the first and second insulating layers 131 and 132 and the second etch stop layer 122 are etched using the first photoresist pattern PR1 as an etch mask. Here, the etch process of the first and second insulating layers 131 and 132 and the second etch stop layer 122 is performed until the first etch stop layer 121 is exposed. Thus, a via 140 having the first width W1 is formed. Subsequently, the first photoresist pattern PR1 is removed.

Referring to FIG. 8, a second photoresist pattern PR2 having an opening of a second width W2 equal to or wider than the width of the first width W1 is formed on the second insulating layer 132 in which the via 140 is formed. Subsequently, the second insulating layer 132 is etched using the second photoresist pattern PR2 as an etch mask. Here, the etch process of the second insulating layer 132 is performed until the second etch stop layer 122 is exposed. Thus, an interconnect area 150 having the second width W2 is firmed within the second insulating layer 132. Subsequently, the second photoresist pattern PR2 is removed. Meanwhile, although it is not shown, before the photoresist for forming the second photoresist pattern PR2 is coated, the via 140 can be filled with a medium formed of a low-k insulating layer, and then the second photoresist pattern PR2 can be formed.

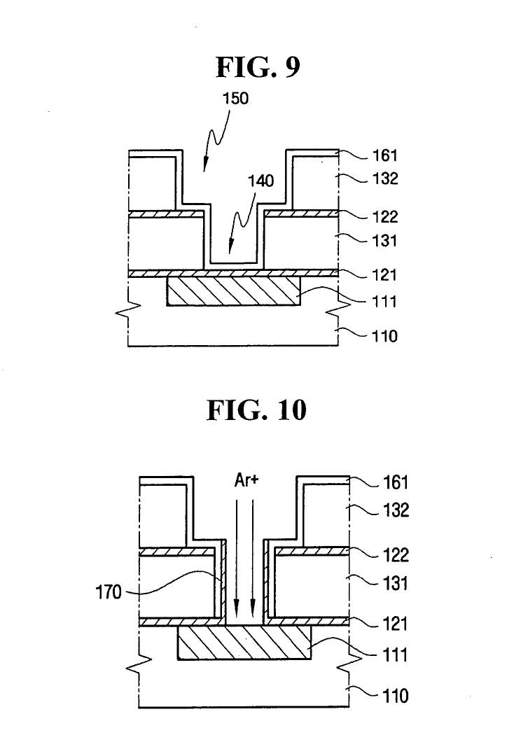

Referring to FIG. 9, a first diffusion barrier layer 161 is formed using a chemical vapor deposition (CVD) method or a physical vapor deposition (PVD) method such as sputtering to have the uniform thickness along steps on the substrate 110. Here, the first diffusion barrier layer 161 can be formed of a Ta layer, a TaN layer, a Ti layer, a TiN layer, a WN layer, or a combined layer thereof.

Referring to FIG. 10, the first diffusion barrier layer 161 and the first etch stop layer 121 on a lower part of the via 140 are removed through an etching process using a sputtering method so that the conductive pattern 111 is exposed. The etching process using the sputtering method accelerates an ionized argon particle Ar⁺ toward a target and pushes atoms forming the target into other positions, thereby etching the target.

More specifically, if the argon particle Ar⁺ of a plasma state is accelerated toward the first diffusion barrier layer 161 on a bottom surface of the via 140, atoms constituting the first diffusion barrier layer 161 and the first etch stop layer 121 on a lower part of the first diffusion barrier layer 161 collide with the argon particle Ar⁺ so that the atoms form a parabolic profile and are resputtered into other positions. Thus, the first diffusion barrier layer 161 positioned on the bottom surface of the via 140 and the first etch stop layer 121 are removed. Here, the atoms constituting the first diffusion barrier layer 161 positioned on the bottom surface of the via 140 and the first etch stop layer 121 are deposited along a sidewall of the via 140 so that a sputtering by-product 170 is formed. Meanwhile, the argon particle Ar⁺ collides with not only the lower part of the via 140 but also all positions on an upper part of the first diffusion barrier layer 161 along the steps on the substrate 110 on performing the etch process using the sputtering method using the argon particle Ar⁺. The etched positions other than the bottom surface of the via 140 are filled with atoms that originate from the first diffusion barrier layer 161 and the first etch stop layer 121. The atoms collide with the released argon particles Ar⁺ so that the atoms form a parabolic profile, and they are resputtered into the etched positions. The collision energy of the released argon particle varies according to the collision position. As a result, the etching process using the sputtering method has no significant influence on the via positions other than the bottom surface of the via 140. Therefore, if etching time in the etch process is properly adjusted, the atoms constituting the bottom surface of the via 140 and having relatively high acceleration are selectively pushed into positions other than the bottom surface so that the atoms are effectively removed from only the bottom surface.

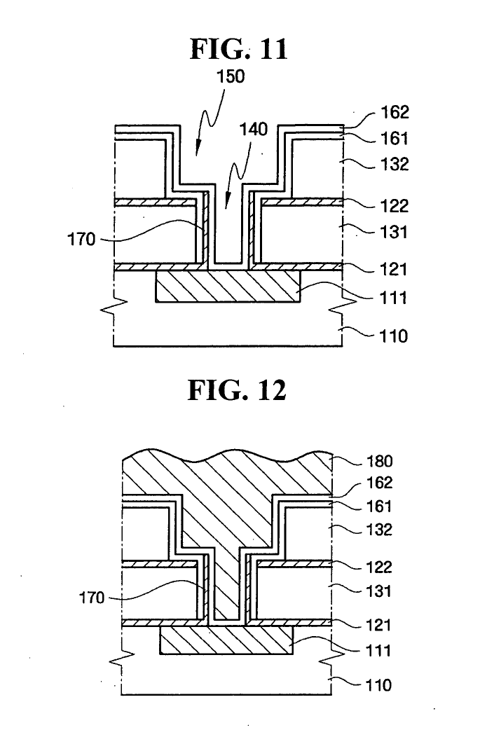

Referring to FIG. 11, a second diffusion barrier layer 162 is formed using the CVD method or the PVD method such as the sputtering to have the uniform thickness along the steps on the substrate 110. Here, the second diffusion barrier layer 162 is formed to cover the first diffusion barrier layer 161 and the sputtering by-product 170.

Here, the second diffusion barrier layer 162 can be formed of a Ta layer, a TaN layer, a Ti layer, a TiN layer, a WN layer, or a combined layer thereof.

Meanwhile, it is preferable that the second diffusion barrier layer 162 is formed of the Ta layer for increasing contact between the second diffusion barrier layer 162 and a conductive material layer 180 which will be described below. Further, it is preferable that the first diffusion barrier layer 161 located inside the second diffusion barrier layer 162 is formed of the TaN layer having a good diffusion barrier capacity for preventing the conductive material layer 180 from being diffused outside the interconnect area 150 and an area of the via 140.

Further, after the conductive pattern 111 is exposed through the etching process using the sputtering method which is the prior process step, the second diffusion barrier layer 162 is immediately deposited without a separate strip process, thereby minimizing a stationary period in an exposed state of the conductive pattern 111.

Referring to FIG. 12, a conductive seed layer is formed on the second diffusion barrier layer 162 formed along the steps on the semiconductor substrate 110, and then the conductive material layer 180 which has enough thickness to fill into the via 140 and the interconnect area 150 is formed by an electrochemical plating (ECP) process.

Here, the conductive material layer 180 can consist of various conductive materials and a combination thereof. It is preferable that the conductive material layer 180 includes copper.

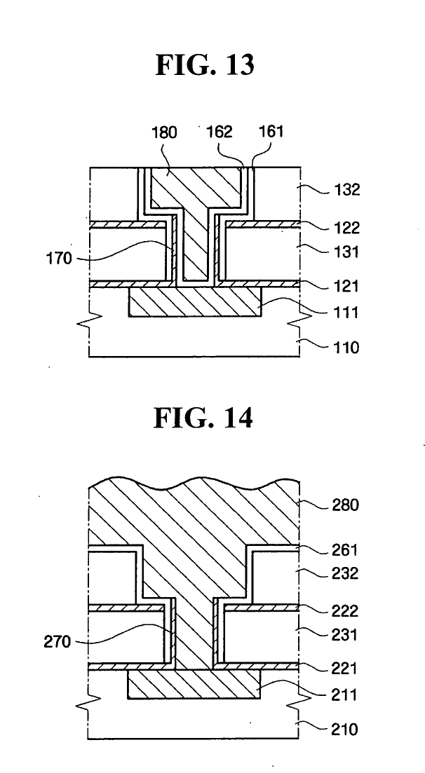

Referring to FIG. 13, since the conductive material layer 180 is filled into the via 140 and the interconnect area 150 by the non-uniform thickness, a chemical mechanical polishing (CMP) process is performed on the conductive material layer 180 to expose the second insulating layer 132 so that a metal interconnect is formed having an even upper surface.

According to the conventional approach, after forming a via and an interconnect area, a dry etch process and a strip process for exposing a conductive pattern are performed. However, according to the first embodiment of the present invention, the first diffusion barrier layer 161 is deposited immediately after forming the via 140 and the interconnect area 150, and then the etching process using the sputtering method is performed for exposing the conductive pattern 111. Thus, since the dry etch process and the strip process of the conventional approach are not performed in the first embodiment of the present invention, the process of the present invention can prevented undercuts of the first and second etch stop layers 121 and 122 from being generated so that the via 140 and the interconnect area 150 can be well filled with the conductive material layer 180.

Further, since the second diffusion barrier layer 162 is immediately deposited without the separate strip process after exposing the conductive pattern 111, the stationary period in the exposed state of the conductive pattern 111 is minimized so that pollution and oxidation of the conductive pattern 111 can be prevented.

Furthermore, since after forming the via 140 and the interconnect area 150, the dry etch process and the strip process for removing oxide on top of the etch stop layers 121 and 122 and the conductive pattern 111 are not performed, the process for forming the metal interconnect is simple, relative to the conventional approach.

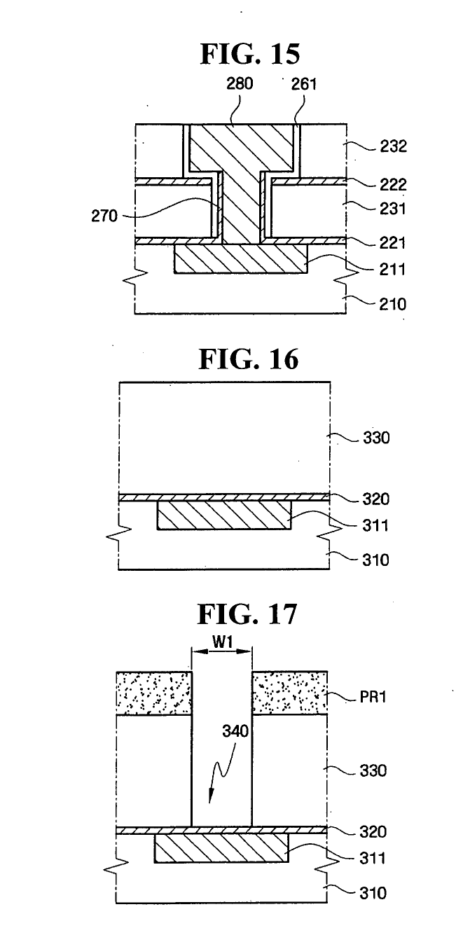

Next, a method of forming a metal interconnect of a semiconductor device according to a second embodiment of the present invention is described with reference to FIGS. 14 and 15.

FIGS. 14 and 15 are cross-sectional views explaining a method of forming a metal interconnect of a semiconductor device according to the second embodiment of the present invention.

Since the method of forming the metal interconnect of the semiconductor device according to the second embodiment of the present invention is substantially the same as the first embodiment of the present invention, except that after removing the first diffusion barrier layer and the first etch stop layer on the lower part of the via by the etching process using the sputtering method, the second diffusion barrier layer 162 is not deposited, the drawings and descriptions according to same processes as the first embodiment are not repeated below.

After the etching process using the sputtering method which is previously described in the first embodiment of the present invention, as shown in FIG. 14, a conductive seed layer is formed on a first diffusion barrier layer 261 formed along steps on a semiconductor substrate 210 and a sputtering by-product 270. Then, a conductive material layer 280 which has enough thickness to fill into a via and an interconnect area is formed by an ECP process.

In this case, after a conductive pattern 211 is exposed through the etching process using the sputtering method which is the prior process step, the conductive material layer 280 is immediately formed without a separate strip process, thereby minimizing a stationary period in which the conductive pattern 211 I exposed.

Here, the conductive material layer 280 can be consisted of various conductive materials and a combination thereof. It is preferable that the conductive material layer 280 includes copper.

Referring to FIG. 15, since the via and the interconnect area are filled with the conductive material layer 280 by the non-uniform thickness, a CMP process is performed on the conductive material layer 280 to expose the second insulating layer 232 so that an even metal interconnect is formed.

Therefore, the second embodiment of the present invention has the same effect as the above-described first embodiment of the present invention. Simultaneously, since a diffusion barrier layer, which is additionally deposited before forming the conductive material layer 280 according to the first embodiment of the present invention, is not deposited in the second embodiment of the present invention, the process for forming the metal interconnect is relatively simpler.

Next, a method of forming a metal interconnect of a semiconductor device according to a third embodiment of the present invention is described referring to FIGS. 16 to 23.

FIGS. 16 to 23 are cross-sectional views showing a method of forming a metal interconnect of a semiconductor device according to the order of process of the metal interconnect according to the third embodiment of the present invention.

As shown in FIG. 16, a semiconductor substrate 310 into which a conductive pattern 311, which will be a lower interconnect, is filled is prepared. An etch stop layer 320 and an insulating layer 330 are successively formed on the semiconductor substrate 310 using the materials and the forming method explained in the first embodiment of the present invention.

Referring to FIG. 17, photoresist is coated on top of the insulating layer 330 and patterned so that a first photoresist pattern PR1, in which an upper surface of the insulating layer 330 is partly exposed as wide as a first width W1, is formed. Here, it is preferable that when an opening of the first photoresist pattern PR1 is projected on the conductive pattern 311, the opening of the first photoresist pattern PR1 is positioned within the width of the conductive pattern 311.

Subsequently, the insulating layer 330 is etched using the first photoresist pattern PR1 as an etch mask. Here, the etch process of the insulating layer 330 is performed until the etch stop layer 320 is exposed. Thus, a via 340 having the first width W1 is formed. Subsequently, the first photoresist pattern PR1 is removed.

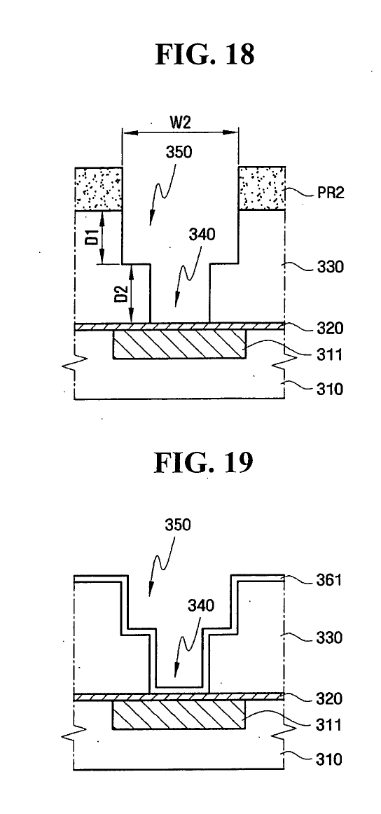

Referring to FIG. 18, a second photoresist pattern PR2 having an opening of a second width W2 equal to or wider than the width of the first width W1 is formed on the insulating layer 330 in which the via 340 is formed. Subsequently, the insulating layer 330 is patterned to etch the insulating layer 330 to a predetermined depth D1 from an upper part of the insulating layer 330 using the second photoresist pattern PR2 as an etch mask. Here, the etch depth D1 of the pattern in the insulating layer 330 can be adjusted by adjusting etching time of the insulating layer 330. Thus, an interconnect area 350 having the second width W2 is formed within the insulating layer 330, and the via 340 having a depth D2 and the first width W1 remains under the interconnect area 350. Here, it is preferable that the depth D1 of the interconnect area 350 and the depth D2 of the via 340 occupy approximately half of a total thickness D1+D2 of the insulating layer 330, respectively.

Subsequently, the second photoresist pattern PR2 is removed. Meanwhile, although it is not shown, before the photoresist for forming the second photoresist pattern PR2 is coated, the via 340 is filled with a medium formed of a low-k insulating layer, or the like, and then the second photoresist pattern PR2 can be formed.

Referring to FIG. 19, a first diffusion barrier layer 361 is formed using a CVD method or a PVD method such as sputtering to have the uniform thickness along steps on the substrate 310. Here, the first diffusion barrier layer 361 can be formed of a Ta layer, a TaN layer, a Ti layer, a TiN layer, a WN layer, or a combined layer thereof.

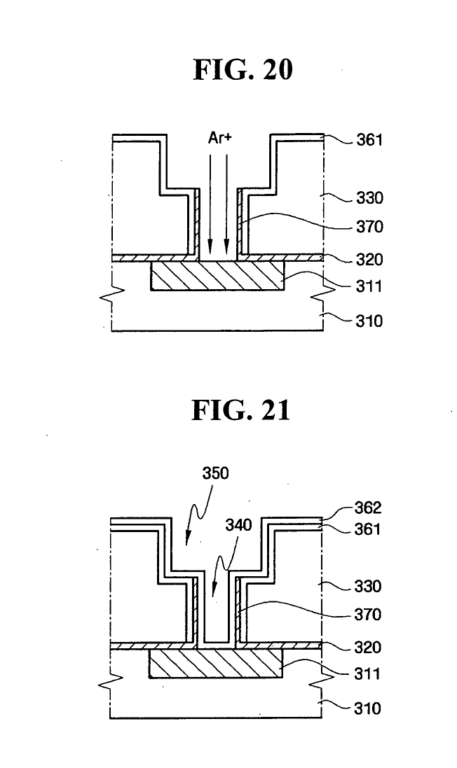

Referring to FIG. 20, the first diffusion barrier layer 361 and the etch stop layer 320 on a lower part of the via 340 are removed through an etching process using a sputtering method so that the conductive pattern 311 is exposed. The etching process using the sputtering method accelerates an ionized argon particle Ar⁺ toward a target and pushes atoms forming the target into positions other than the target, thereby etching the target.

More specifically, if the argon particle Ar⁺ of a plasma state is accelerated toward the first diffusion barrier layer 361 on a bottom surface of the via 340, atoms constituting the first diffusion barrier layer 361 and the etch stop layer 320 on a lower part of the first diffusion barrier layer 361 collide with the argon particle Ar⁺ so that the atoms form a parabolic profile and are resputtered into other positions. Thus, the first diffusion barrier layer 361 positioned on the bottom surface of the via 340 and the etch stop layer 320 are removed. Here, the atoms constituting the first diffusion barrier layer 361 positioned on the bottom surface of the via 340 and the etch stop layer 320 are deposited along a sidewall of the via 340 so that a sputtering by-product 370 is formed. Meanwhile, the argon particle Ar⁺ collides with not only a lower part of the via 340 but also all positions on an upper part of the first diffusion barrier layer 361 along the steps on the substrate 310 on performing the etch process using the sputtering method using the argon particle Ar⁺. The etched positions other than the bottom surface of the via 340 are filled with atoms that originate from the first diffusion barrier layer 361 and the first etch stop layer 320. The atoms collide with the released argon particles Ar⁺ so that the atoms form a parabolic profile, and they are resputtered into the etched positions. The collision energy of the released argon particle varies according to the collision position. As a result, the etching process using the sputtering method has no significant influence on the via positions other than the bottom surface of the via 340. Therefore, if etching time in the etch process is properly adjusted, the atoms constituting the bottom surface of the via 340 and having relatively high acceleration are selectively pushed into positions other than the bottom surface so that the atoms are effectively removed from only the bottom surface.

Referring to FIG. 21, a second diffusion barrier layer 362 is formed using the CVD method or the PVD method such as the sputtering to have the uniform thickness along the steps on the substrate 310. Here, the second diffusion barrier layer 362 is formed to cover the first diffusion barrier layer 361 and the sputtering by-product 370.

Here, the second diffusion barrier layer 362 can be formed of a Ta layer, a TaN layer, a Ti layer, a TiN layer, a WN layer, or a combined layer thereof.

Meanwhile, it is preferable that the second diffusion barrier layer 362 is formed of the Ta layer for increasing contact between the second diffusion barrier layer 362 and a conductive material layer 380 which will be described below. Further, it is preferable that the first diffusion barrier layer 361 located inside the second diffusion barrier layer 362 is formed of the TaN layer having a good diffusion barrier capacity for preventing the conductive material layer 380 from being diffused outside the interconnect area 350 and an area of the via 340.

Further, after the conductive pattern 311 is exposed through the etching process using the sputtering method which is the prior process step, the second diffusion barrier layer 362 is immediately deposited without a separate strip process, thereby minimizing a stationary period during which the conductive pattern 311 is exposed.

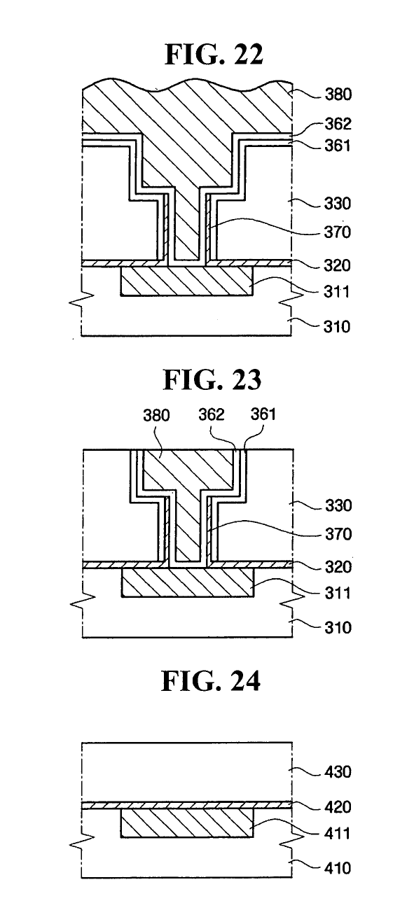

Referring to FIG. 22, a conductive seed layer is formed on the second diffusion barrier layer 362 formed along the steps on the semiconductor substrate 310, and then the conductive material layer 380, which is thick enough to fill the via 340 and the interconnect area 350, is formed by an ECP process.

Here, the conductive material layer 380 is composed of one of a variety of different conductive materials or a combination thereof. It is preferable that the conductive material layer 380 includes copper.

Referring to FIG. 23, since the conductive material layer 380 is filled into the via 340 and the interconnect area 350 at a non-uniform thickness, a CMP process is performed on the conductive material layer 380 to expose the insulating layer 330 so that an even metal interconnect is formed.

Meanwhile, although the first diffusion barrier layer 361 is deposited before the etch process using the sputtering method and the second diffusion barrier layer 362 is additionally deposited after the etch process using the sputtering method in the third embodiment of the present invention, the deposition of the second diffusion barrier layer 362 can be removed from the process and the conductive material layer 380 can be formed immediately.

Therefore, the third embodiment of the present invention has the same effect as the above-described first embodiment of the present invention.

Next, a method of forming a metal interconnect of a semiconductor device according to a fourth embodiment of the present invention is explained referring to FIGS. 24 to 30.

Although the first, second and third embodiments of the present invention were explained giving a dual damascene process as an example, a fourth embodiment of the present invention is explained giving a single damascene process as an example.

FIGS. 24 to 30 are cross-sectional views showing a method of forming a metal interconnect of a semiconductor device according to the order of process of the metal interconnect according to the fourth embodiment of the present invention.

As shown in FIG. 24, a semiconductor substrate 410 into which a conductive pattern 411 is filled is prepared. An etch stop layer 420 and an insulating layer 430 are successively formed on the semiconductor substrate 410 using the materials and the forming method explained in the first embodiment of the present invention. The conductive pattern 411 may be a lower interconnect. Further, the conductive pattern 411 may be a via or a contact hole for electrically connecting the lower interconnect or a conductive area to an upper interconnect to be formed at a later time.

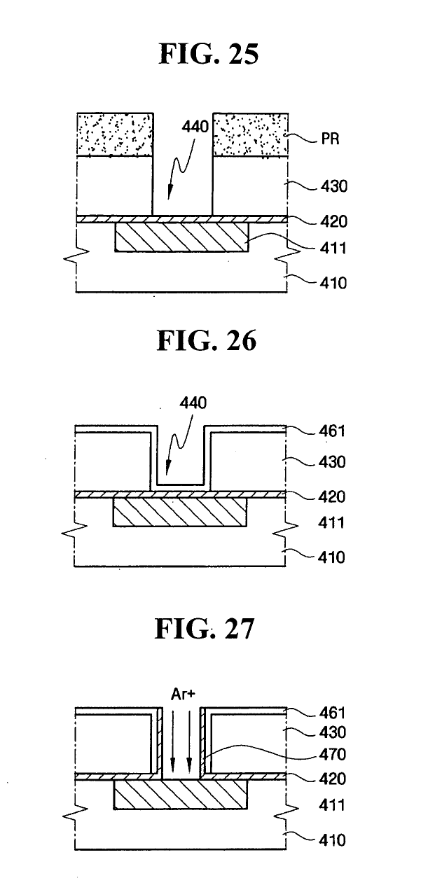

Referring to FIG. 25, photoresist is coated on top of the insulating layer 430 and patterned so that a photoresist pattern PR, in which an upper surface of the insulating layer 430 is partly exposed, is formed.

Subsequently, the insulating layer 430 is etched using the photoresist pattern PR as an etch mask. Here, the etch process of the insulating layer 430 is performed until the etch stop layer 420 is exposed. Thus, an opening 440 for exposing the etch stop layer 420 is formed. Subsequently, the photoresist pattern PR is removed.

Referring to FIG. 26, a first diffusion barrier layer 461 is formed using a CVD method or a PVD method such as sputtering to have a uniform thickness along steps on the substrate 410. Here, the first diffusion barrier layer 461 can be formed of a Ta layer, a TaN layer, a Ti layer, a TiN layer, a WN layer, or a combined layer thereof.

Referring to FIG. 27, the first diffusion barrier layer 461 on a lower part of the opening 440 and the etch stop layer 420 are removed through an etching process using a sputtering method so that the conductive pattern 411 is exposed. In the etching process using the sputtering method, atoms of compounds on a bottom surface of the opening 440 having relatively high acceleration are selectively pushed into positions other than the bottom surface by the same operations as those described in the first, second and third embodiments of the present invention so that the conductive pattern 411 is exposed.

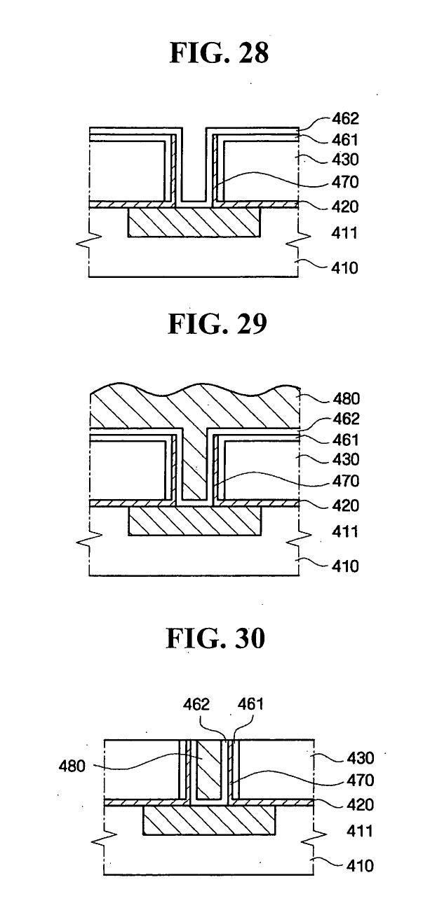

Referring to FIG. 28, a second diffusion barrier layer 462 is formed using the CVD method or the PVD method such as the sputtering to have the uniform thickness along the steps on the substrate 410. In this case, the second diffusion barrier layer 462 is formed to cover the first diffusion barrier layer 461 and a sputtering by-product 470.

Here, the second diffusion barrier layer 462 can be formed of a Ta layer, a TaN layer, a Ti layer, a TiN layer, a WN layer, or a combined layer thereof.

Meanwhile, it is preferable that the second diffusion barrier layer 462 is formed of the Ta layer for increasing contact between the second diffusion barrier layer 462 and a conductive material layer 480 which will be described below. Further, it is preferable that the first diffusion barrier layer 461 located inside the second diffusion barrier layer 462 is formed of the TaN layer having a good diffusion barrier capacity for preventing the conductive material layer 480 from being diffused outside an area of the opening 440.

Further, after the conductive pattern 411 is exposed through the etching process using the sputtering method which is the prior process step, the second diffusion barrier layer 462 is immediately deposited without a separate strip process, thereby minimizing a stationary period in an exposed state of the conductive pattern 411.

Referring to FIG. 29, a conductive seed layer is formed on the second diffusion barrier layer 462 formed along the steps on the semiconductor substrate 410, and then the conductive material layer 480, which is thick enough to fill the opening 440, is formed by an ECP process.

Here, the conductive material layer 480 is composed of one of a variety of different conductive materials or a combination thereof. It is preferable that the conductive material layer 480 includes copper.

Referring to FIG. 30, since the conductive material layer 480 is filled into the opening 440 by the non-uniform thickness, a CMP process is performed on the conductive material layer 480 to expose the insulating layer 430 so that an even metal interconnect is formed.

Meanwhile, although the first diffusion barrier layer 461 is deposited before the etch process using the sputtering method and the second diffusion barrier layer 462 is additionally deposited after the etch process using the sputtering method in the fourth embodiment of the present invention, the deposition of the second diffusion barrier layer 462, is optional and can be skipped, in which case the conductive material layer 480 can be formed immediately thereafter.

Therefore, the fourth embodiment of the present invention has an effect similar to the above-described first embodiment of the present invention.

While this invention has been particularly shown and described with references to preferred embodiments thereof, it will be understood by those skilled in the art that various changes in form and details may be made herein without departing from the spirit and scope of the invention as defined by the appended claims.

As described above, the method of forming the metal interconnects according to the present invention has the following effects.

A profile failure such as an undercut of an etch stop layer is prevented so that a conductive material can be conformally filled into a via or an interconnect area.

In addition, after a conductive pattern on a semiconductor substrate is exposed, a next process subsequent to the exposure is successively performed without a stationary period during which the conductive pattern would otherwise be exposed. In this manner, pollution and oxidation of the conductive pattern can be prevented.

Further, since the dry etch process and the strip process for exposing the conductive pattern which were used in the prior art are not performed, the process for forming the metal interconnect can thus be simplified.

What is claimed is:

1. A method of forming a metal interconnect of a semiconductor device comprising:
successively forming an etch stop layer and an insulating layer on a semiconductor substrate into which a conductive pattern is filled;
patterning the insulating layer and forming an opening to expose the etch stop layer;
forming a first diffusion barrier layer along inner surfaces of the opening;
removing the first diffusion barrier layer and the etch stop layer on a bottom surface of the opening through an etch process using a sputtering method; and
filling the opening with a conductive material which is electrically connected to the conductive pattern.

2. The method of claim 1, wherein the opening is a via or an interconnect region.

3. The method of claim 1, further comprising, after the removing of the first diffusion barrier layer and the etch stop layer on the bottom surface of the opening, forming a second diffusion barrier layer on the inner surfaces of the opening.

4. The method of claim 3, wherein the first and second diffusion barrier layers are formed of a Ta layer, a TaN layer, a Ti layer, a TiN layer, a WN layer, or combinations thereof.

5. The method of claim 4, wherein the first diffusion barrier layer is formed of a TaN layer and the second diffusion barrier layer is formed of a Ta layer.

6. The method of claim 3, wherein the first and second diffusion barrier layers are formed by a sputtering method or a chemical vapor deposition (CVD) method.

7. The method of claim 1, wherein the etch process using the sputtering method in the removing of the first diffusion barrier layer and the etch stop layer is used to accelerate an argon particle in a plasma state toward the first diffusion barrier layer and the etch stop layer on the bottom surface of the opening and to push atoms forming the first diffusion barrier layer and the etch stop layer at the bottom surface of the opening into other positions, thereby removing the first diffusion barrier layer and the etch stop layer.

8. A method of forming a metal interconnect of a semiconductor device comprising:
successively forming a first etch stop layer and a first insulating layer on a semiconductor substrate into which a conductive pattern is filled;
successively forming a second etch stop layer and a second insulating layer on the first insulating layer;
patterning the second insulating layer, the second etch stop layer and the first insulating layer to forming a via to expose the first etch stop layer;
patterning the second insulating layer to form an interconnect area at a top region of the via having a width equal to or greater than the via;
forming a first diffusion barrier layer along inner surfaces of the via;
removing the first diffusion barrier layer and the first etch stop layer on a bottom surface of the via through an etch process using a sputtering method; and
filling the via and the interconnect area with a conductive material which is electrically connected to the conductive pattern.

9. The method of claim 8, further comprising, after the removing of the first diffusion barrier layer and the first etch stop layer on the bottom surface of the via, forming a second diffusion barrier layer on the inner surfaces of the via.

10. The method of claim 9, wherein the first and second diffusion barrier layers are formed of a Ta layer, a TaN layer, a Ti layer, a TiN layer, a WN layer, or combinations thereof.

11. The method of claim 10, wherein the first diffusion barrier layer is formed of a TaN layer and the second diffusion barrier layer is formed of a Ta layer.

12. The method of claim 9, wherein the first and second diffusion barrier layers are formed by a sputtering method or a chemical vapor deposition (CVD) method.

13. The method of claim 1, wherein the etch process using the sputtering method in the removing of the first diffusion barrier layer and the first etch stop layer is used to accelerate an argon particle in a plasma state toward the first diffusion barrier layer and the etch stop layer on the bottom surface of the via and to push atoms forming the first diffusion barrier layer and the etch stop layer at the bottom surface of the via into other positions, thereby removing the first diffusion barrier layer and the etch stop layer.

14. A method of forming a metal interconnect of a semiconductor device comprising:
successively forming an etch stop layer and an insulating layer on a semiconductor substrate into which a conductive pattern is filled;
patterning the insulating layer and forming a via to expose the etch stop layer;
patterning the insulating layer to etch the insulating layer, on which the via is formed, to a predetermined depth from an upper part of the insulating layer and adjusting the predetermined depth by adjusting the etching time of the insulating layer to form an interconnect area at a top region of the via having a width equal to or greater than the via;
forming a first diffusion barrier layer along steps on inner surfaces of the via;
removing the first diffusion barrier layer and the etch stop layer on a bottom surface of the via through an etch process using a sputtering method; and
filling the via and the interconnect area with a conductive material which is electrically connected to the conductive pattern.

15. The method of claim 14, further comprising, after the removing of the first diffusion barrier layer and the etch stop layer on the bottom surface of the via, forming a second diffusion barrier layer along the inner surfaces of the via.

16. The method of claim 15, wherein the first and second diffusion barrier layers are formed of a Ta layer, a TaN layer, a Ti layer, a TiN layer, a WN layer, or combinations thereof.

17. The method of claim 16, wherein the first diffusion barrier layer is formed of a TaN layer and the second diffusion barrier layer is formed of a Ta layer.

18. The method of claims 15, wherein the first and second diffusion barrier layers are formed by a sputtering method or a chemical vapor deposition (CVD) method.

19. The method of claim 14, wherein the etch process using the sputtering method in the removing of the first diffusion barrier layer and the etch stop layer is used to accelerate an argon particle in a plasma state toward the first diffusion barrier layer and the etch stop layer on the bottom surface of the via and to push atoms forming the first diffusion barrier layer and the etch stop layer at the bottom surface of the via into other positions, thereby removing the first diffusion barrier layer and the etch stop layer.
